(19) United States
(12) Patent Application Publication
(10) Pub. No.: US 2012/0218703 A1
(43) Pub. Date: Aug. 30, 2012

(54) Circuit Board Assemblies and Data Processing Systems Including the Same

(76) Inventors: Jeong Hyeon Cho, Hwaseong-si (KR); Myung Hee Sung, Hwaseong-si (KR); Kyoung Sun Kim, Uijeongbu-si (KR); Seung Jin Seo, Suwon-si (KR); Jung Joon Lee, Seoul (KR)

(21) Appl. No.: 13/240,439

(22) Filed: Sep. 22, 2011

(30) Foreign Application Priority Data
Feb. 24, 2011 (KR) 10-2011-0016500

(51) Int. Cl. G06F 1/16; H05K 1/00; H05K 1/14

(52) U.S. Cl. 361/679.31; 361/784; 361/749

(57) ABSTRACT

A circuit board assembly includes a first circuit board having an electrical connection circuit on a surface thereof. A second circuit board is on the surface of the first circuit board. A first memory socket is mounted on the second circuit board. The first memory socket is only electrically connected to the electrical connection circuit through the second circuit board. A second memory socket is mounted on the second circuit board. The second memory socket that is only electrically connected to the electrical connection circuit through the second circuit board.

### CROSS-REFERENCE TO RELATED APPLICATIONS

This application claims priority under 35 U.S.C. §119(a) from Korean Patent Application No. 10-2011-0016500 filed on Feb. 24, 2011, the disclosure of which is hereby incorporated herein by reference in its entirety.

### BACKGROUND

The present inventive concept relates to circuit boards, such as a main circuit board (motherboard), and more particularly, to such circuit boards including memory sockets.

On a main circuit board of a computer system typically, a central processing unit (CPU) socket for mounting a CPU and each of a plurality of memory sockets for mounting each of a plurality of system memories are mounted. The main board generally includes a plurality of memory sockets which may extend a system memory to, for example, improve performance of the computer system.

When a memory module is not mounted in all of the plurality of memory sockets, a reflection wave will generally occur in data signal lines connected to a memory socket where a memory module is not mounted. The reflection wave may cause degradation of signal characteristics of the system memory operating at high speed.

### SUMMARY

Some embodiments of the present invention provide a circuit board assembly including a first circuit board having an electrical connection circuit on a surface thereof. A second circuit board is on the surface of the first circuit board. A first memory socket is mounted on the second circuit board. The first memory socket is only electrically connected to the electrical connection circuit through the second circuit board. A second memory socket is mounted on the second circuit board. The second memory socket that is only electrically connected to the electrical connection circuit through the second circuit board.

In other embodiments, the first memory socket and the second memory socket are removably coupled to the first circuit board and the second circuit board by at least one mechanical supporter. The second circuit board may have an upper surface and a lower surface and the first memory socket and the second memory socket may be mounted on the upper surface. The lower surface may face the surface of the first circuit board. The lower surface of the second circuit board may include a ground plane extending proximate signal lines of the second circuit board that electrically connect the memory sockets to the electrical connection circuit.

In further embodiments, the second circuit board is a printed circuit board (PCB) and each of the memory sockets includes at least one elastic stopper that is electrically connected to the electrical connection circuit. The electrical connection circuit is an elastic stopper connection unit and the circuit board assembly further includes a central processing unit (CPU) socket mounted on the first circuit board.

In other embodiments, the second circuit board is two circuit boards, a first memory socket circuit board and a second memory socket circuit board. A portion of the second memory socket circuit board overlaps the first memory socket circuit board with the first memory socket circuit board between the second memory socket board and the first circuit board. The second memory socket is mounted to the second memory socket circuit board in the portion of the second memory socket circuit board that overlaps the first memory socket circuit board. The circuit board assembly may include a third memory socket that is mounted on the second memory socket circuit board in a portion of the second memory socket circuit board that does not overlap the first memory socket circuit board.

In further embodiments, the memory sockets are mounted on the second circuit board so that a memory module inserted therein extends substantially parallel to the surface of the first circuit board. The second circuit board may be a flexible circuit board and the second memory socket may be mounted stacked on the first memory socket. The first memory socket may be electrically connected to the electrical connection circuit via an electrical connection through the second circuit board and the second memory socket may only be electrically connected to the electrical connection circuit through the electrical connection through the second circuit board of the first memory socket. The memory sockets may be mounted so that a memory module inserted in each of the memory sockets extends substantially parallel to the surface of the first circuit board in a same direction or in an opposite direction.

In other embodiments, each of the first memory socket and the second memory socket is configured to receive a memory module therein that is an unbuffered dual in-line memory module (UDIMM), a registered dual in-line memory module (RDIMM), a low profile dual in-line memory module (LPDIMM), a load reduced dual in-line memory module (LRDIMM), a mini dual in-line memory module (MiniDIMM) or a small outline dual in-line memory module (SoDIMM).

In yet other embodiments, the circuit board assembly further includes a central processing unit (CPU) inserted in a CPU socket on the first circuit board and a memory module inserted in the first memory socket. A memory module may be inserted in the second memory socket or no memory module may be inserted in the second memory socket. The circuit board assembly may also include a host interface mounted on the first circuit board and communicatively coupled to the CPU and the memory modules. Each of the memory sockets may also include a connection member configured to maintain a secure physical connection with the respective memory module inserted therein.

In further embodiments, a circuit board assembly includes a first circuit board having an electrical connection circuit on a surface thereof. A second circuit board is on the surface of the first circuit board. A first memory socket is coupled to the first circuit board and has an electrical connection to the electrical connection circuit through the second circuit board. A second memory socket is coupled to the first circuit board that is only electrically connected to the electrical connection circuit through the electrical connection of the first memory socket.

In yet further embodiments, a data processing system includes a circuit board assembly as described above and further includes a memory controller communicatively coupled to the circuit board assembly. A display and an input device are communicatively coupled to the circuit board assembly. A memory device is communicatively coupled to the memory controller.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic block diagram illustrating a data processing system according to some embodiments;

FIGS. 2A and 2B are schematic diagrams illustrating a memory module, a memory socket and a circuit board as illustrated in FIG. 1 in further detail, respectively, from a partially perspective side view and a plane view;

FIG. 3 is a schematic side view illustrating a first memory socket A as illustrated in FIG. 2B in further detail;

FIG. 4 is a schematic side view illustrating a first memory socket and a second memory socket as illustrated in FIG. 1 in further detail;

FIG. 5 is a schematic side view illustrating the first memory socket, a second memory socket and a third memory socket as illustrated in FIG. 2B in further detail;

FIG. 6 is a schematic side view illustrating a circuit board according to further embodiments;

FIGS. 7A to 7C are schematic side views illustrating a circuit board according to yet further embodiments; and

FIG. 8 is a schematic block diagram of a memory system including the data processing system illustrated in FIG. 1 according to further embodiments.

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the invention to those skilled in the art, and the present inventive concept will only be defined by the appended claims. Like reference numerals refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Embodiments of the present invention will now be described with reference to circuit boards. In particular, for purposes of the following description, the embodiments will be described with reference to a main circuit board (motherboard), which will be referred to herein as a “main board.” Where a circuit board, such as a main board, includes a plurality of memory sockets, when a memory module is inserted in only some of the plurality of memory sockets, a reflection wave may occur in a data signal line connected to a memory socket where the memory module is not inserted. The reflection wave may cause degradation of signal characteristics of a memory module operating at high speed. A circuit board, such as a main board, according to some embodiments of the present inventive concept only has a first memory socket directly connected to the main board. When a second memory socket is also connected/mounted, a printer circuit board (PCB) is mounted between the main board and the first memory socket and the second memory socket is connected to the main board electrically through the PCB. As a result, some embodiments may improve data signal characteristics (or integrity) of a memory socket for inserting a memory module, and a data processing system having the same.

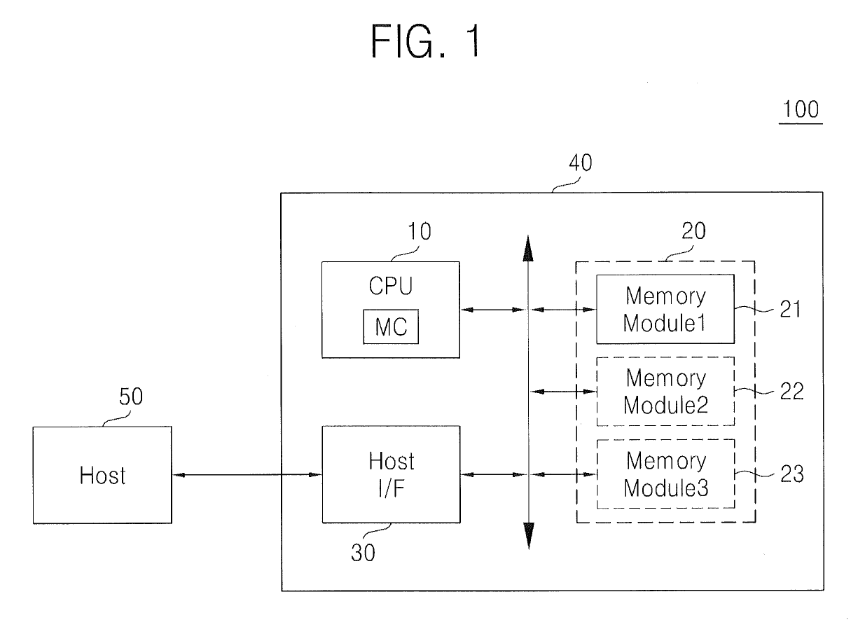

FIG. 1 is a block diagram illustrating a data processing system according to some embodiments. Referring to FIG. 1, the data processing system 100 includes a central processing unit 10 (CPU), a system memory 20 and a host interface 30 on a main board 40 and a host 50.

The CPU 10 may include a memory controller MC for controlling the system memory 20. According to some embodiments, the memory controller MC may be embodied as a part of the CPU 10 or embodied independently from the CPU 10.

The system memory 20 may store programs and/or data the CPU 10 may accesses. For example, the system memory 20 may be embodied in a static random access memory (SRAM) and/or a dynamic random access memory (DRAM). The illustrated system memory 20 includes a first memory module 21. In addition, the illustrated system memory 20 may further include a second memory module 22 and a third memory module 23, for example, to expand memory capacity.

The host interface 30 may interface with the host 50 under the control of the CPU 10. For example, the host interface 30 may be embodied in a Serial Advanced technology attachment (SATA) interface, a parallel advance technology attachment (PATA) interface, a universal serial bus (USB) interface, a peripheral component interconnect (PCI) interface, a peripheral component interconnect express (PCI-EXPRESS) interface or a serial attached SCSI (SAS) interface. In some embodiments, more than one of these interfaces may be supported on the main board 40 by the Host interface 30.

The main board 40 may includes a CPU socket for mounting the CPU 10 on the main board 40 and a first memory socket for mounting the first memory module 21 on the main board 40. The main board 40 may further include a second memory socket and a third memory socket to allowing additional memory to be coupled to the main board 40 and the CPU 10 thereon.

The host 50 is communicatively coupled to perform data communication with the CPU 10 through the host interface 30. The data processing system 100 may be included in a hard disk drive (HDD) or a solid state drive (SSD). The data processing system 100 may be included in a laptop computer, a personal computer (PC), a work station or a server.

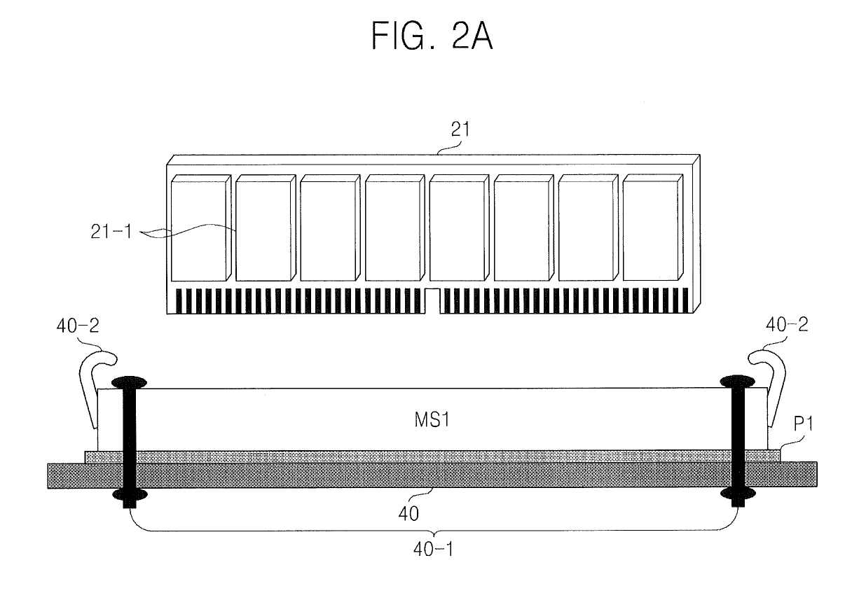

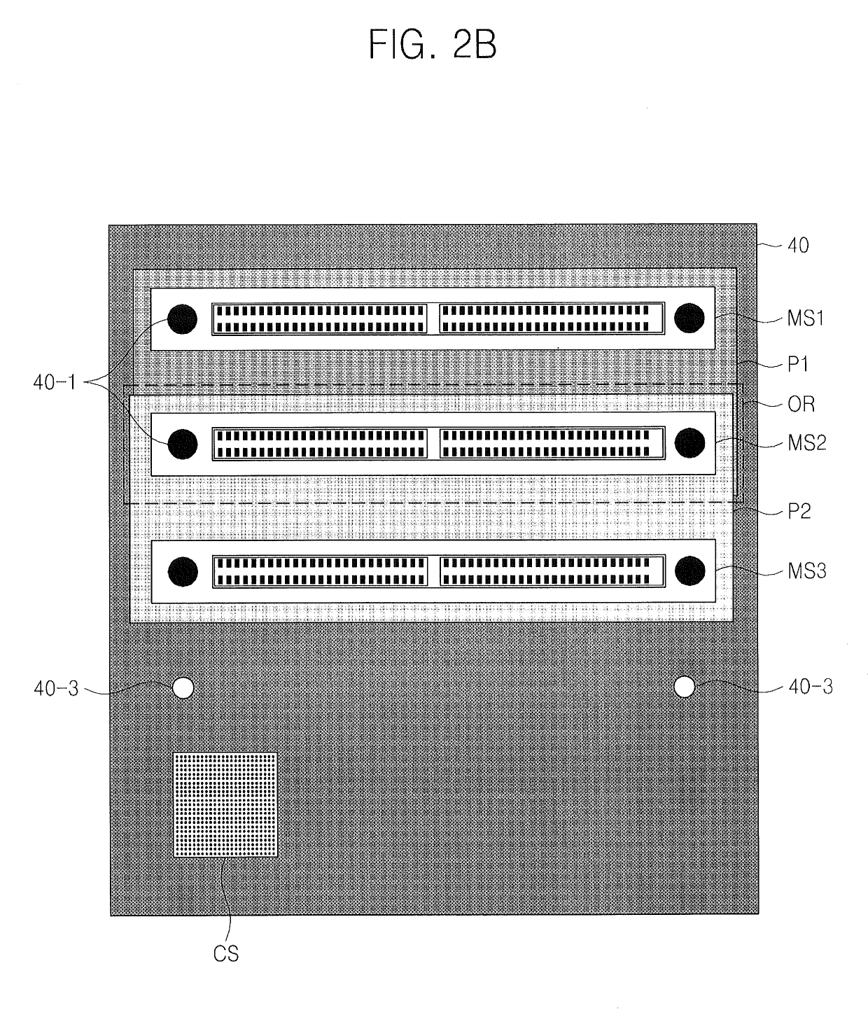

FIGS. 2A to 2B are diagrams illustrating the memory module, a memory socket and a main board illustrated in FIG. 1 in particular embodiments. FIG. 2A illustrates a front side view of the main board 40 illustrated in FIG. 1, and FIG. 2B illustrates a plane view of the main board 40 illustrated in FIG. 1. For convenience of explanation, the first memory module 21 and a first memory socket MS1 are both illustrated in FIG. 2A. The first memory module 21 is shown in partially exploded perspective view while the main board 40 with the memory socket MS1 mounted thereon are in side view.

Referring to FIGS. 1, 2A and 2B, a plurality of memory devices 21-1 are mounted on a front surface of the first memory module 21. According to some embodiments, a dynamic random access memory (DRAM), a static random access memory (SRAM), a flash memory, a phase change memory or a resistive memory may be mounted on the memory module 21 as the plurality of memory devices 21-1. In addition, to further expand a memory capacity of the first memory module 21, another plurality of memory devices may be mounted on a rear (or back) surface of the first memory module 21.

The first memory module 21 may be, for example, an Unbuffered Dual In-Line Memory Module (UDIMM), a Registered Dual In-Line Memory Module (RDIMM), Low Profile Dual In-Line Memory Module (LPDIMM), a Load Reduced Dual-In-Line Memory Module (LRDIMM), a Mini Dual In-Line Memory Module (MiniDIMM) or a Small Outline Dual In-Line Memory Module (SoDIMM). The UDIMM is a DRAM module used for personal computer (PC). The RDIMM is a DRAM module used for server and workstation. The SoDIMM is a DRAM module used for laptop computers.

The second memory module 22 and a third memory module 23 may have an identical or a similar configuration to the first memory module 21. Each of the second memory module 22 and the third memory module 23 may be, for example, a UDIMM, a RDIMM or a SoDIMM.

The main board 40 includes a CPU socket CS (FIG. 2B) for mounting a CPU 10 and a first memory socket MS1 for mounting the first memory module 21. As seen in FIG. 2A, the first memory module 21 is inserted in a direction perpendicular to the main board 40 in the first memory socket MS1.

To expand a memory capacity of the system memory 20, at least one of a second memory socket MS2 for mounting the second memory module 22 and a third memory socket MS3 for mounting the third memory module 23 may be mounted on the main board 40 as seen in FIG. 2B. More particularly, as seen in FIG. 2B, a first printed circuit board (PCB) P1 electrically connects the first memory socket MS1 with the second memory socket MS2 and/or a second PCB P2 electrically connects the second memory socket MS2 with the third memory socket MS3. The PCBs P1, P2 are mounted on the main board 40. For example, each of the first PCB P1 and the second PCB P2 may be embodied as a thin PCB or a flexible PCB.

As seen in FIG. 2A, the first memory socket MS1 may include a connection member shown as a hook 40-2, for maintaining a secure physical connection with the first memory module 21. In addition, each of the second memory socket MS2 and the third memory socket MS3 may include a hook for maintaining a secure connection with each of the second memory module 22 and the third memory module 23.

The first PCB P1 may be attached or detached to or from the main board 40. Likewise, the second PCB P2 may be attached/detached to/from the main board 40. As illustrated in FIG. 2B, the first PCB P1 and the second PCB P2 may be arranged to be overlapped. The second memory socket MS2 is in the illustrated embodiments is coupled (attached/detached to/from) in an overlapped region OR. As shown in FIG. 2B, a portion of the second PCB P2 may be arranged to be overlapped with a portion of the first PCB P1 in the overlapped region OR.

As illustrated in FIG. 2B, the main board 40 includes a plurality of holes 40-3 configured to receive and secure a supporter 40-1 (FIGS. 2A and 2B) to connect each of the first memory socket MS1, the second memory socket MS2 and the third memory socket MS3 to the main board 40.

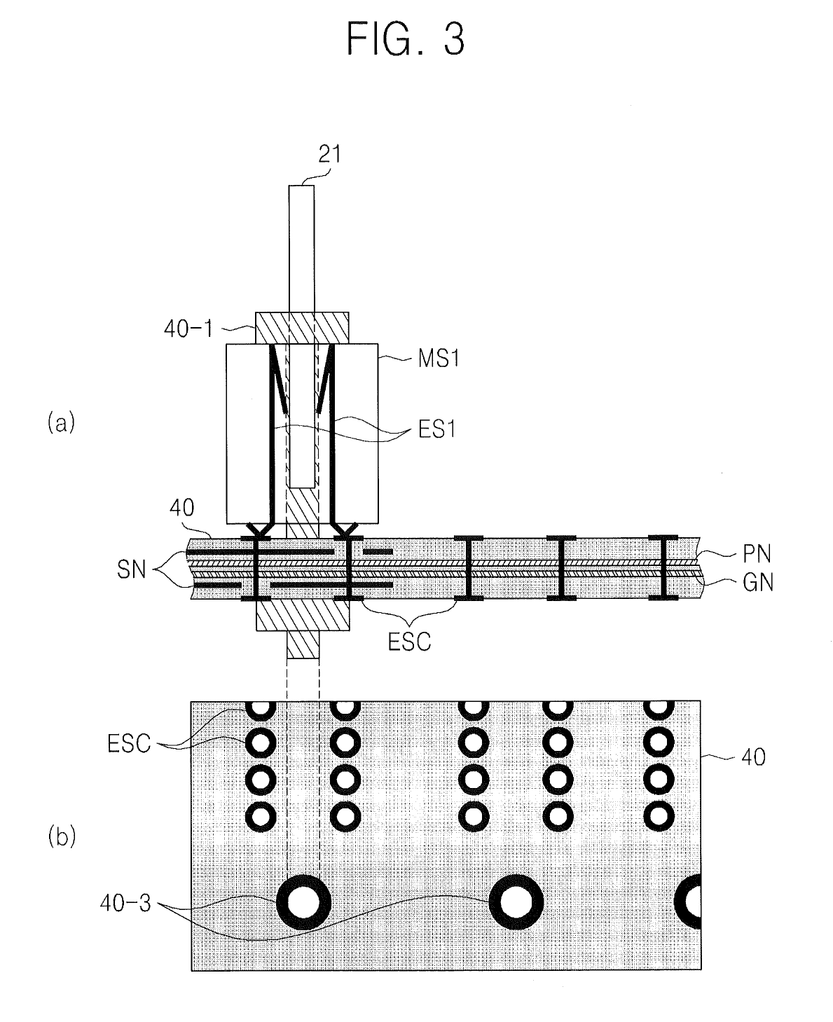

FIG. 3 is a diagram illustrating embodiments of the first memory socket 21 of FIG. 2B. Referring to the cutaway side view portion (a) and the bottom plane view portion (b) (that may be substantially identical in arrangement to the top view with the memory socket MS1) of FIG. 3, only the first memory socket MS1 is shown mounted on the main board 40. The supporter 40-1 is inserted in a hole 40-3 in the main board 40. The main board 40 and the first memory socket MS1 are fixedly coupled by the supporter 40-1. The first memory module 21 is inserted in the first memory socket MS1. Each of data lines of the first memory module 21 is electrically connected to each of corresponding elastic stoppers ES1 by the first memory socket MS1. Each of the elastic stoppers ES1 is electrically connected to an elastic stopper connection unit ESC of the main board 40.

The main board 40 includes a power line PN, a ground line GN and a plurality of signal lines SN extending therein. Each of a plurality of elastic stopper connection units ESC is connected to corresponding one of the plurality of signal lines SN.

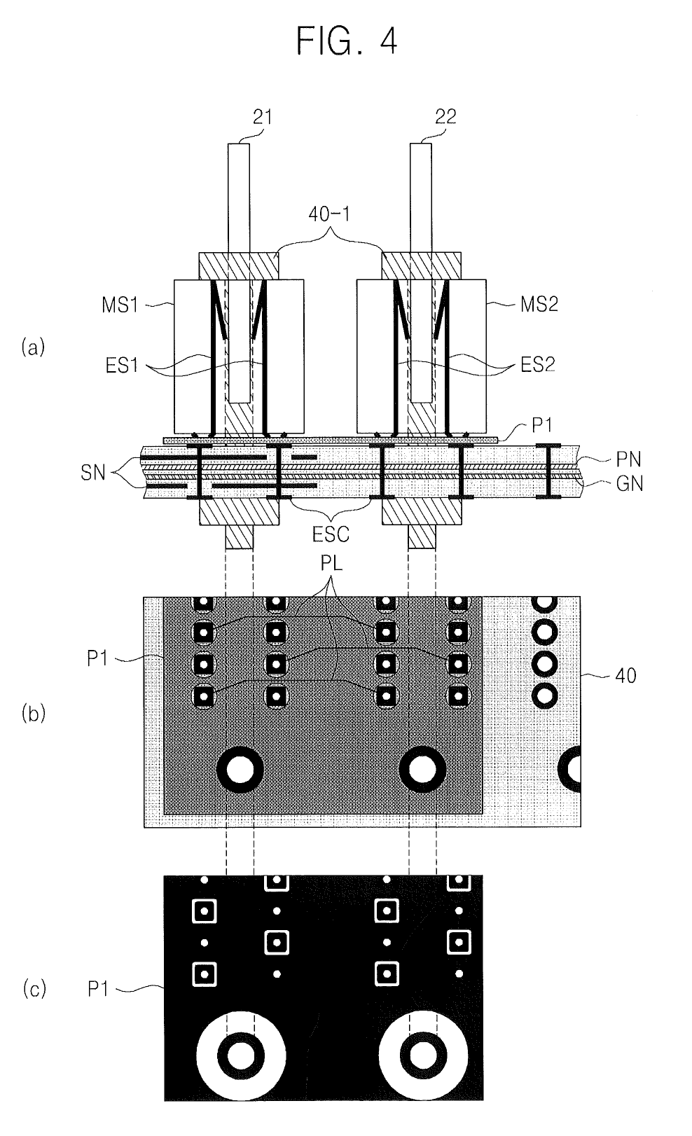

FIG. 4 is a diagram illustrating embodiments of the first memory socket 21 and the second memory socket 22 of FIG. 1. Referring to FIG. 4, the first memory socket MS1 and the second memory socket MS2 are mounted on the main board 40. Each of the first memory socket MS1 and the second memory socket MS2 is fixed on the main board 40 by at least one respective supporter 40-1.

The first memory module 21 is inserted in the first memory socket MS1. Each of the data lines of the first memory module 21 is electrically connected to corresponding ones of the elastic stoppers ES1. The second memory module 22 is inserted in the second memory socket MS2. Each of the data lines of the second memory module 22 is electrically connected to corresponding ones of the elastic stoppers ES2.

More particularly, an elastic stopper ES1 of the first memory socket MS1 is connected to the first PCB P1 and a signal line SN of the main board 40. The surfaces of the PCB P1 are illustrated in the plane views of portions (b) and (c) of FIG. 4. At an upper part (or surface) of the first PCB P1, a plurality of signal lines PL are routed for connecting the first memory socket MS1 and the second memory socket MS2. An elastic stopper ES2 of the second memory socket MS2 is connected to a corresponding signal line among the plurality of signal lines Ph A lower part (or surface) of the first PCB P1 is connected to a signal line SN of the main board 40. In addition, the lower part of the first PCB P1 (other than signal lines) may be set to a ground voltage (e.g., a ground plane as seen in portion (c) of FIG. 4) so that data of the signal line SN may be transmitted more reliably/stably.

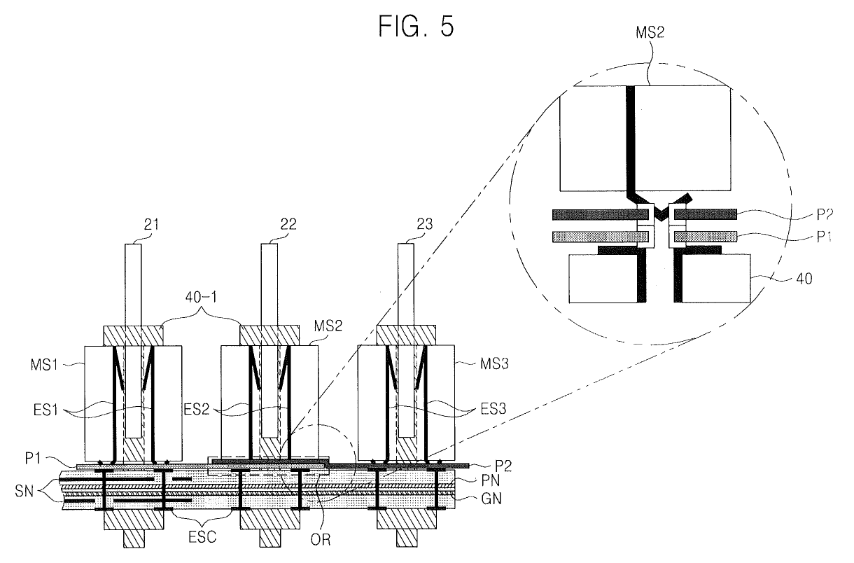

FIG. 5 is a diagram illustrating embodiments of the first memory socket MS1, the second memory socket MS2 and the third memory socket MS3 of FIG. 2B. Referring to FIG. 5, the first memory socket MS1, the second memory socket MS2 and the third memory socket MS3 are mounted on the main board 40. Each of the first memory socket MS1, the second memory socket MS2 and the third memory socket MS3 are shown as fixedly connected to the main board 40 by respective supporter(s) 40-1. The first memory module 21 is inserted in the first memory socket MS1. Each of data lines of the first memory module 21 is electrically connected to a corresponding one of the elastic stoppers ES1. The second memory module 22 is inserted in the second memory socket MS2. Each of data lines of the second memory module 22 is electrically connected to a corresponding one of the elastic stoppers ES2. The third memory module 23 is inserted in the third memory socket MS3. Each of data lines of the third memory module 23 is electrically connected to a corresponding one of the elastic stoppers ES3.

The elastic stoppers ES1 of the first memory socket MS1 are connected to the first PCB P1 and a corresponding elastic stopper connection unit ESC of the main board 40. The elastic stopper connection unit ESC is connected to signal lines SN of the main board 40.

The first PCB P1 and the second PCB P2 are shown configured to be attached or detached in an overlapped relationship. That is, the second PCB P2 is coupled to a portion of the first PCB P1. The second memory socket MS2 is coupled in a region OR in which the first PCB P1 and the second PCB P2 are overlapped. The elastic stopper ES2 of the second memory socket MS2 is connected to the second PCB P2.

A lower end/surface of the second PCB P2 is configured to be connected to the upper end/surface of the first PCB P1. The third memory socket MS3 is coupled to a portion of the second PCB P2, which portion is not overlapped with the second PCB P2. The elastic stopper(s) ES3 of the third memory socket MS3 are electrically connected to the second PCB P2.

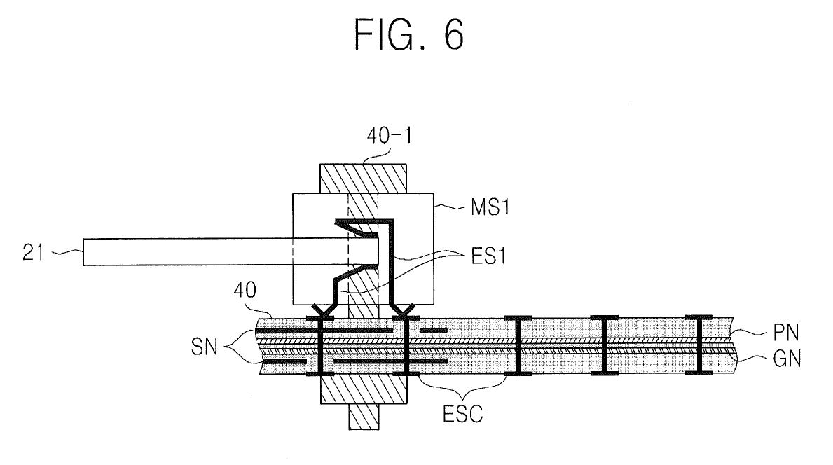

FIG. 6 is a side view diagram illustrating a main board according to other embodiments. Referring to FIG. 6, it will be assumed for purposes of explanation that the main board 40 is a sized to be small enough for use in a laptop computer. The first memory socket MS1 is mounted on the main board 40. The supporter 40-1 is inserted in a hole of the main board 40. The first memory socket MS1 is fixed on the main board 40 by the supporter 40-1.

The first memory module 21 is inserted to the first memory socket MS1 in a direction that extends parallel to the main board 40. A memory module in the form of SoDIMM, for example, may be mounted in the first memory socket MS1. Each of data lines of the first memory module 21 is connected to each of corresponding elastic stoppers ES1. Each of the elastic stoppers ES1 is connected to the elastic stopper connection unit ESC of the main board 40. The elastic stopper connection unit ESC is connected to the signal lines SN of the main board 40.

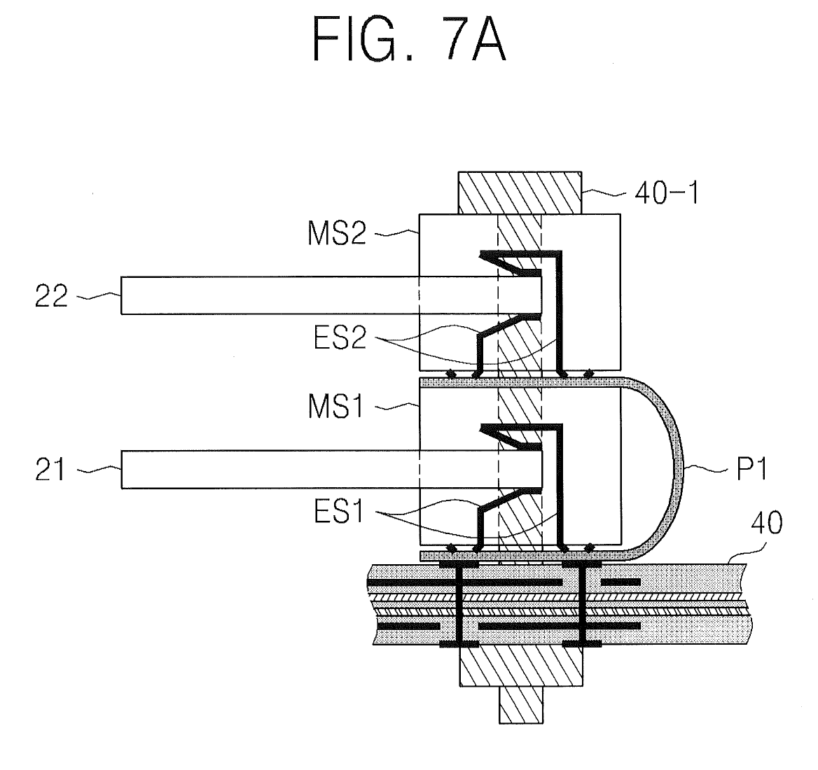

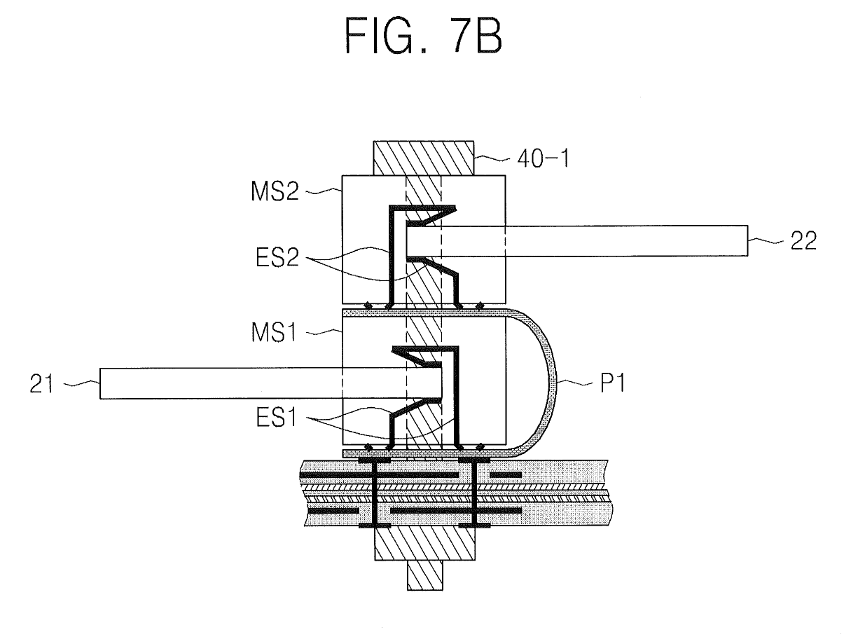

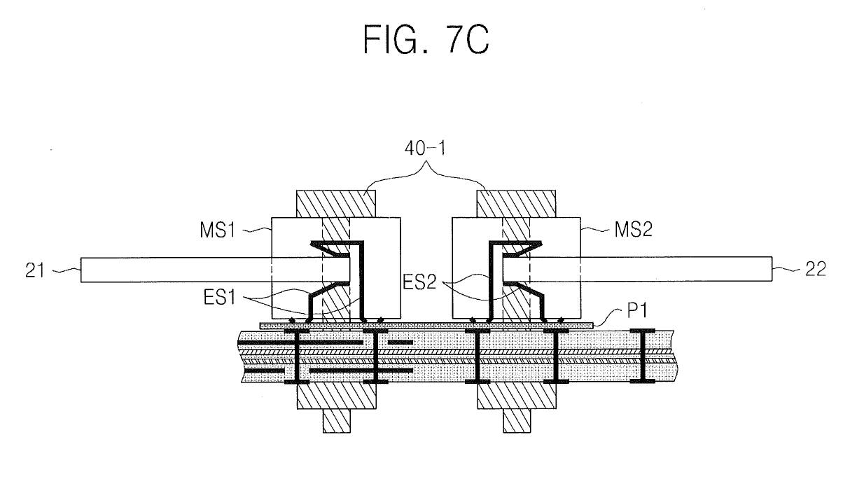

FIGS. 7A to 7C illustrate further embodiments of the main board of FIG. 6. Referring to the side view of FIG. 7A, the second memory socket MS2 is stacked on the first memory socket MS1 so as to receive another memory module running in parallel with the first memory module and the first memory socket MS1 and the second memory socket MS2 are connected by the first PCB P1.

The first memory module 21 is inserted in the first memory socket MS1 in a direction that extends in parallel to the main board 40. The second memory socket MS2 is oriented to receive a memory module in the same direction as the first memory socket MS1. The first PCB P1 is a flexible PCB. The first PCB P1 bends and electrically connects the first memory socket MS1 and the second memory socket MS2. Each of the elastic stoppers ES1 of the first memory socket MS1 is connected to the elastic stopper connection unit ESC of the main board 40 through the first PCB P1. Each of the elastic stoppers ES2 of the second memory socket MS2 is connected to the elastic stopper connection unit ESC of the main board 40 through the first PCB P1.

Referring to FIG. 7B, the second memory socket MS2 is stacked on the first memory socket MS1 so as to receive a memory module in an opposite direction to a memory module received in the first memory socket MS1, and the first memory socket MS1 and the second memory socket MS2 are connected by the first PCB P1.

The first memory module 21 is inserted in the first memory socket MS1 in a direction parallel to the main board 40. The second memory module 22 is inserted in the second memory socket MS2 that is oriented so that the second memory module 22 extends therefrom in a direction opposite that of the first memory module 21 extending from the first memory socket MS2. The first PCB P1 is a flexible PCB. The first PCB P1 bends and connects electrically the first memory socket MS1 and the second memory socket MS2. Each of the elastic stoppers ES1 of the first memory socket MS1 is connected to the elastic stopper connection unit ESC of the main board 40 through the first PCB P1. Each of the elastic stoppers ES2 of the second memory socket MS2 is connected to the elastic stopper connection unit ESC of the main board 40 through the first PCB P1.

Referring to FIG. 7C, the first memory socket MS1 and the second memory socket MS2 are attached or detached (removably coupled) to the main board 40 on the same plane, instead of the stacked relationship of FIG. 7B, and electrically connected by the first PCB P1.

The first memory module 21 is inserted in the first memory socket MS1 in a direction parallel to the main board 40. The second memory socket MS2 is inserted in an opposite direction to the first memory socket MS1. The first PCB P1 electrically connects the first memory socket MS1 and the second memory socket MS2. Each of the elastic stoppers ES1 of the first memory socket MS1 is connected to the elastic stopper connection unit ESC of the main board 40 through the first PCB P1. Each of the elastic stoppers ES2 of the second memory socket MS2 is connected to the elastic stopper connection unit ESC of the main board 40 through the first PCB P1.

In some embodiments, such as those in FIGS. 7A and 7B, the connection of the first memory socket MS1 may directly through the PCB P1 to the underlying elastic stopper connection unit ESC of the main board 40. As used herein in this context, “directly electrically connected” means that the electrical connection extends through the PCB P1 but not laterally along the PCB P1. The electrical connection to the underlying elastic stopper connection unit ESC of the main board 40 for the second and third memory socket MS2, MS3 is not direct in that the connection must first extend laterally along the PCB P1 or PCB P1 and PCB P2. More generally, the second and third memory socket MS2, MS3 are only electrically connected to the elastic stopper connection unit ESC of the main board 40 by the electrical connection of the first memory socket MS1 to the elastic stopper connection unit ESC of the main board 40.

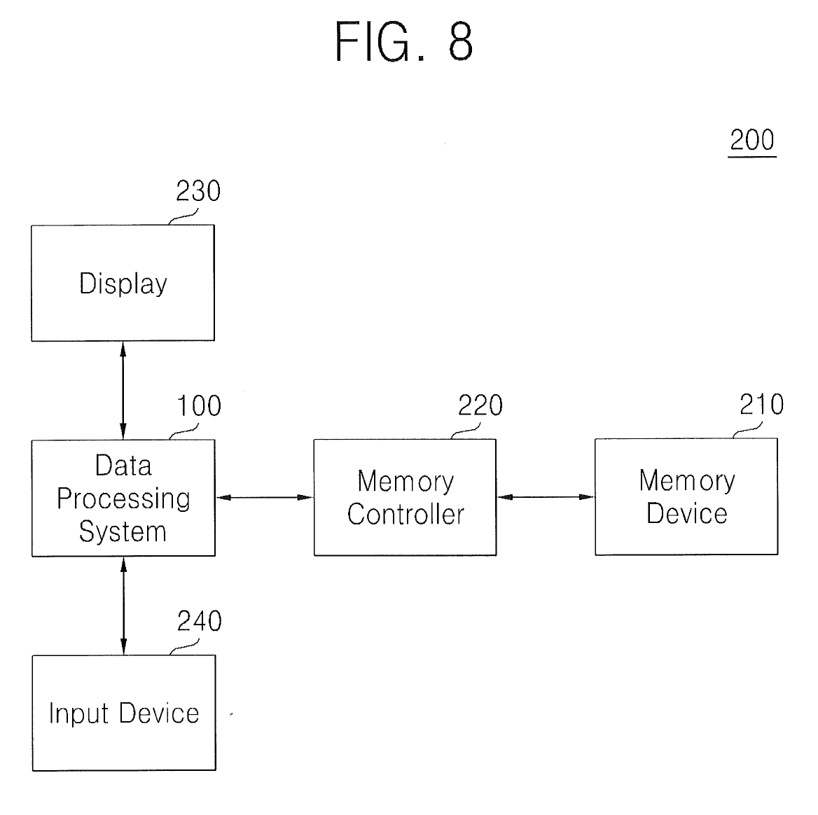

FIG. 8 illustrates some embodiments of a memory system including the data processing system illustrated in FIG. 1. Referring to FIGS. 1 and 8, a computer system 200 including a data processing system 100 illustrated in FIG. 1 may be embodied in a personal computer (PC), a network server, a tablet PC or a net-book.

The computer system 200 includes the data processing system 100, a memory device 210, a memory controller 220, which may control a data processing operation of the memory device 210, a display 230 and a input device 240.

The data processing system 100 may display data stored in the memory device 210 through the display 230 responsive to data input through the input device 240. For example, the input device 240 may be embodied in a pointing device such as a touch pad or a computer mouse, a keypad or a keyboard. The data processing system 100 may control a general operation of the computer system 200 and an operation of the memory controller 220.

The memory controller 220, which may control an operation of the memory device 210, may be embodied as a part of the data processing system 100 or in a separate chip from the data processing system 100 according to some embodiments.

The circuit board of the present inventive concept may prevent a reflection wave caused by a memory socket where a memory module is not mounted/inserted. The circuit board of the present inventive concept may also reduce a cost by mounting/inserting a memory socket only as needed.

The foregoing is illustrative of the present inventive concept and is not to be construed as limiting thereof. Although a few embodiments of the present inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the appended claims. The present inventive concept is defined by the following claims, with equivalents of the claims to be included therein.

1. A circuit board assembly, comprising:
a first circuit board having an electrical connection circuit on a surface thereof;
a second circuit board on the surface of the first circuit board;
a first memory socket mounted on the second circuit board that is only electrically connected to the electrical connection circuit through the second circuit board; and
a second memory socket mounted on the second circuit board that is only electrically connected to the electrical connection circuit through the second circuit board.

2. The circuit board assembly of claim 1, wherein the first memory socket and the second memory socket are removably coupled to the first circuit board and the second circuit board by at least one mechanical supporter.

3. The circuit board assembly of claim 1, wherein the second circuit board has an upper surface and a lower surface and wherein the first memory socket and the second memory socket are mounted on the upper surface and the lower surface faces the surface of the first circuit board and wherein the lower surface of the second circuit board includes a ground plane extending proximate signal lines of the second circuit board that electrically connect the memory sockets to the electrical connection circuit.

4. The circuit board assembly of claim 1, wherein the second circuit board comprises a printed circuit board (PCB) and wherein each of the memory sockets includes at least one elastic stopper that is electrically connected to the electrical connection circuit and wherein the electrical connection circuit comprises an elastic stopper connection unit and wherein the circuit board assembly further comprises a central processing unit (CPU) socket mounted on the first circuit board.

5. The circuit board assembly of claim 1, wherein the second circuit board comprises a first memory socket circuit board and a second memory socket circuit board and wherein a portion of the second memory socket circuit board overlaps the first memory socket circuit board with the first memory socket circuit board between the second memory socket board and the first circuit board and wherein the second memory socket is mounted to the second memory socket circuit board in the portion of the second memory socket circuit board that overlaps the first memory socket circuit board.

6. The circuit board assembly of claim 5, further comprising a third memory socket that is mounted on the second memory socket circuit board in a portion of the second memory socket circuit board that does not overlap the first memory socket circuit board.

7. The circuit board assembly of claim 1, wherein the memory sockets are mounted on the second circuit board so that a memory module inserted therein extends substantially parallel to the surface of the first circuit board.

8. The circuit board assembly of claim 1, wherein the second circuit board comprises a flexible circuit board and wherein the second memory socket is mounted stacked on the first memory socket.

9. The circuit board of claim 8, wherein the first memory socket is electrically connected to the electrical connection circuit via an electrical connection through the second circuit board and the second memory socket is only electrically connected to the electrical connection circuit through the electrical connection through the second circuit board of the first memory socket.

10. The circuit board assembly of claim 8, wherein the memory sockets are mounted so that a memory module inserted in each of the memory sockets extends substantially parallel to the surface of the first circuit board in a same direction.

11. The circuit board assembly of claim 8, wherein the memory sockets are mounted so that a memory module inserted in each of the memory sockets extends substantially parallel to the surface of the first circuit board in an opposite direction.

12. The circuit board assembly of claim 8, wherein each of the first memory socket and the second memory socket is configured to receive a memory module therein that is an unbuffered dual in-line memory module (UDIMM), a registered dual in-line memory module (RDIMM), a low profile dual in-line memory module (LPDIMM), a load reduced dual in-line memory module (LRDIMM), a mini dual in-line memory module (MiniDIMM) or a small outline dual in-line memory module (SoDIMM).

13. The circuit board assembly of claim 1, wherein each of the first memory socket and the second memory socket is configured to receive a memory module therein that is an unbuffered dual in-line memory module (UDIMM), a registered dual in-line memory module (RDIMM), a low profile dual in-line memory module (LPDIMM), a load reduced dual in-line memory module (LRDIMM), a mini dual in-line memory module (MiniDIMM) or a small outline dual in-line memory module (SoDIMM).

14. The circuit board assembly of claim 1, further comprising:
a central processing unit (CPU) inserted in a CPU socket on the first circuit board; and
a memory module inserted in the first memory socket and no memory module inserted in the second memory socket.

15. The circuit board assembly of claim 1, further comprising:
a central processing unit (CPU) inserted in a CPU socket on the first circuit board;
a first memory module inserted in the first memory socket; and
a second memory module inserted in the second memory socket.

16. The circuit board assembly of claim 15, further comprising a host interface mounted on the first circuit board and communicatively coupled to the CPU and the memory modules.

17. The circuit board assembly of claim 15, wherein each of the memory sockets further comprises a connection member configured to maintain a secure physical connection with the respective memory module inserted therein.

18. A circuit board assembly, comprising:
a first circuit board having an electrical connection circuit on a surface thereof;
a second circuit board on the surface of the first circuit board;
a first memory socket coupled to the first circuit board and having an electrical connection to the electrical connection circuit through the second circuit board; and
a second memory socket coupled to the first circuit board that is only electrically connected to the electrical connection circuit through the electrical connection of the first memory socket.

19. A data processing system including the circuit board assembly of claim 18 and further comprising:
a memory controller communicatively coupled to the circuit board assembly;
a display communicatively coupled to the circuit board assembly;
an input device communicatively coupled to the circuit board assembly; and
a memory device communicatively coupled to the memory controller.

20. A main board comprising:
a printed circuit board (PCB) attached or detached to/from the main board; and
a first memory socket and a second memory socket each attached or detached to/from the PCB,
wherein the PCB connects the first memory socket and the second memory socket electrically.

21-34. (canceled)
